(19) United States
(12) Patent Application Publication
(10) Pub. No.: US 2026/0109142 A1
(43) Pub. Date: Apr. 23, 2026

(54) METHOD OF FABRICATING DISPLAY DEVICE AND APPARATUS FOR FABRICATING DISPLAY DEVICE

(71) Applicant: Samsung Display Co., LTD., Yongin-si (KR)

(72) Inventors: Dong Ho PARK, Yongin-si (KR); Tae Young PARK, Yongin-si (KR); Byung Moo KIM, Yongin-si (KR); Chang Ook LEE, Yongin-si (KR); Jung Hyeok LIM, Yongin-si (KR); Jae Heung CHO, Yongin-si (KR)

(73) Assignee: Samsung Display Co., LTD., Yongin-si (KR)

(21) Appl. No.: 19/186,031

(22) Filed: Apr. 22, 2025

(30) Foreign Application Priority Data
Oct. 17, 2024 (KR) 10-2024-0142348

(51) Int. Cl. B32B 37/10; H01L 21/67; H01L 21/683

(52) U.S. Cl. CPC B32B 37/1018; H10P 72/0441; H10P 72/78; B32B 2457/20

(57) ABSTRACT

Provided herein are a method of fabricating a display device and an apparatus for fabricating the display device. The method includes: forming a panel and a resin-type adhesive layer using a first jig; forming a cover window using a second jig; and coupling the panel to the cover window. The forming of the panel and the resin-type adhesive layer includes: placing the panel and the resin-type adhesive layer on a stage including an opening; and supporting, by a roller, a lower surface of the panel exposed through the opening of the stage.

### CROSS-REFERENCE TO RELATED APPLICATION(S)

This application claims priority to and benefits of Korean Patent Application No. 10-2024-0142348 under 35 U.S.C. § 119, filed in the Korean Intellectual Property Office on Oct. 17, 2024, the entire contents of which are incorporated herein by reference.

### BACKGROUND

### 1. Technical Field

Various embodiments of the disclosure relate to a method of fabricating a display device and an apparatus for fabricating the display device.

### 2. Description of Related Art

Recently, as interest in information display increases, research and development on display devices have been continuously conducted. In addition, as the application field of the display devices expands further, interest in flexible display devices is also increasing.

The display devices may include a display panel, and a window disposed on the display panel to protect the display panel. To allow the display devices to have flexible characteristics, the display panel and the window need to be appropriately formed.

### SUMMARY

An aspect of the disclosure is directed to a method of fabricating a display device and an apparatus for fabricating the display device in which a display panel and a cover window are thoroughly attached to each other.

An aspect of the disclosure is directed to a method of fabricating a display device and an apparatus for fabricating the display device in which a process of forming the display panel and the cover window is appropriately performed.

An aspect of the disclosure is directed to a method of fabricating a display device and an apparatus for fabricating the display device in which jigs for performing the forming process reliably secure (or hold) the display panel and the cover window.

An aspect of the disclosure is directed to a method of fabricating a display device and an apparatus for fabricating the display device in which process steps may be simplified.

An embodiment may provide a method of fabricating a display device, including: forming a panel and a resin-type adhesive layer using a first jig; forming a cover window using a second jig; and coupling the panel to the cover window.

In an embodiment, the forming of the panel and the resin-type adhesive layer may include: placing the panel and the resin-type adhesive layer on a stage, the stage including an opening; and supporting, by a roller, a lower surface of the panel that is exposed through the opening of the stage.

In an embodiment, the forming of the panel and the resin-type adhesive layer may include: spacing the stage and the panel apart from each other while the roller supports the lower surface of the panel; and placing the first jig including a curved surface under a lower portion of the panel.

In an embodiment, the forming of the panel and the resin-type adhesive layer may include: attaching a pin to a central portion of the lower portion of the panel; and pulling the panel by the pin while the roller supports the lower portion of the panel.

In an embodiment, the forming of the panel and the resin-type adhesive layer may include: attaching vacuum members to a peripheral portion surrounding the central portion of the panel; pulling the panel by the vacuum members; and moving the roller from the central portion toward an edge portion of the panel. Attaching the vacuum members to the peripheral portion surrounding the central portion of the panel may be performed after attaching the pin to the central portion of the lower portion of the panel.

In an embodiment, the forming of the panel and the resin-type adhesive layer may include sequentially placing the panel on the first jig in a direction from the central portion toward the edge portion.

In an embodiment, the forming of the cover window may include: coupling a center clamp to a central portion of a lower portion of the cover window; coupling a side clamp to a side of the cover window; and pushing, by the center clamp, the cover window in a direction from the cover window toward the second jig while the side clamp maintains a position of the side of the cover window.

In an embodiment, pushing the cover window may include reducing a curvature of the cover window. The forming of the cover window may include bringing the second jig adjacent to the cover window such that the central portion of the cover window contacts the second jig.

In an embodiment, the forming of the cover window may include: pushing the cover window by the second jig; and pulling the cover window by the center clamp.

In an embodiment, the forming of the cover window may include sequentially placing the cover window on the second jig in a direction from the central portion toward the side such that the cover window is formed to correspond to the second jig.

In an embodiment, coupling the panel and the cover window may include coupling the formed panel and the formed resin-type adhesive layer with the formed cover window.

An embodiment may provide an apparatus for fabricating a display device, including: a first fabrication apparatus that forms a panel; and a second fabrication apparatus that forms a cover window. The first fabrication apparatus may include: a first jig including a curved surface oriented toward the panel; a pin coupled to a central portion of a lower portion of the panel, the pin being movable in upward and downward directions; and rollers supporting the panel from below the panel, the rollers being movable from the central portion of the panel toward an edge portion of the panel. The second fabrication apparatus may include: a second jig including a curved surface oriented toward the cover window; a center clamp coupled to a central portion of a lower portion of the cover window, the center clamp being movable in upward and downward directions; and side clamps coupled to sides of the cover window.

In an embodiment, the rollers may include a first roller and a second roller spaced apart from each other and each having a shape extending in a direction. The curved surface of the first jig may be oriented toward the lower portion of the panel.

In an embodiment, the pin may pull the central portion of the panel while the rollers support the lower portion of the panel.

In an embodiment, the pin may include a suction pad that couples to the lower portion of the panel.

In an embodiment, the apparatus may further include vacuum members disposed under the lower portion of the panel, and coupled to the panel around the central portion of the panel. The vacuum members may be movable in the upward and downward directions.

In an embodiment, the vacuum members may include a first vacuum member disposed on a first side of the pin on which the first roller is positioned, and a second vacuum member disposed on a second side of the pin on which the second roller is positioned.

In an embodiment, the vacuum members may pull the panel after the pin pulls the lower portion of the panel. The rollers may support the lower portion of the panel and move from the central portion of the panel toward the edge portion while the pin and the vacuum members pull the panel.

In an embodiment, the second jig may include a convex surface facing the cover window.

In an embodiment, the center clamp may push the cover window in a direction from the cover window toward the second jig while the side clamps hold the cover window. The second jig may move in a direction from the second jig toward the cover window while the side clamps hold the cover window.

### BRIEF DESCRIPTION OF THE DRAWINGS

FIG. 1 is a schematic sectional view illustrating a display device in accordance with an embodiment.

FIG. 2 is a schematic flowchart illustrating a method of fabricating the display device in accordance with an embodiment.

FIGS. 3 to 22 are schematic views illustrating, by process steps, the method of fabricating the display device in accordance with an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Various embodiments of the disclosure relate to a method of fabricating a display device and an apparatus for fabricating the display device. Hereinafter, the method of fabricating the display device and the apparatus for fabricating the display device in accordance with an embodiment will be described with reference to the attached drawings.

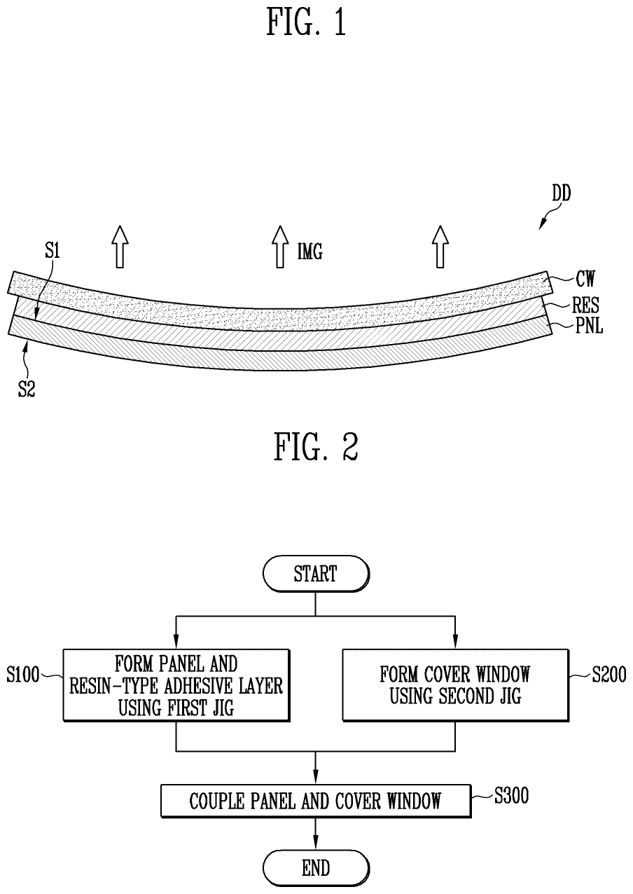

Hereinafter, a display device DD in accordance with an embodiment will be described with reference to FIG. 1.

FIG. 1 is a schematic sectional view illustrating the display device DD in accordance with an embodiment.

Referring to FIG. 1, the display device DD may include a panel PNL, a resin-type adhesive layer RES, and a cover window CW. The display device DD may output image information IMG to a front surface.

The panel PNL may be a display panel. The panel PNL may emit light. The panel PNL may include various light sources. For example, the panel PNL may be an organic light emitting panel including an organic light emitting element, or may be an inorganic light emitting panel including an inorganic light emitting element (e.g., a micro light emitting diode (micro LED)). However, embodiments are not limited to a specific example.

The panel PNL may have flexible characteristics. For example, at least a portion of the panel PNL may be curved. In an embodiment, the panel PNL may include a relatively flexible substrate. The substrate may include polyimide or the like, but embodiments are not limited thereto.

The panel PNL may include a first surface S1 and a second surface S2. The first surface S1 may be oriented toward the front surface of the display device DD. The second surface S2 may be oriented toward a rear surface of the display device DD.

The panel PNL may have a curved cross-sectional shape. The panel PNL may include a curved surface. The panel PNL may be curved inward in a direction in which the image information IMG is emitted or displayed. For example, the panel PNL may be curved such that the first surface S1 may be oriented (or face) inward. The first surface S1 may be a concave surface, and the second surface S2 may be a convex surface.

The resin-type adhesive layer RES may couple the panel PNL and the cover window CW to each other. The resin-type adhesive layer RES may be interposed (or disposed) between the panel PNL and the cover window CW, and may have a cross-sectional shape corresponding to an upper surface of the panel PNL and a lower surface of the cover window CW.

The resin-type adhesive layer RES may include resin material having characteristics similar to that of an optically clear adhesive (OCA). For example, the resin-type adhesive layer RES may include acrylic or epoxy-based material. However, embodiments are not limited to the aforementioned example.

The cover window CW may be placed (or disposed) on the resin-type adhesive layer RES. The cover window CW may be placed (or disposed) on the first surface S1 of the panel PNL.

The cover window CW may have a curved cross-sectional shape. The cover window CW may include a curved surface. The cover window CW may be curved inward in a direction in which the image information IMG is emitted. For example, the cover window CW may be curved such that an outer surface of the cover window CW may be oriented (or face) inward. The outer surface of the cover window CW may be a concave surface.

In an embodiment, as the display device DD has a curved shape, there may be provided a display device DD that is applicable to various electronic devices and has improved user aesthetics and convenience. For example, the display device DD in accordance with an embodiment may be applied to an automotive display. However, embodiments are not limited to the aforementioned example.

In an embodiment, the panel PNL and the cover window CW may be bonded to each other by resin material. For example, as the resin-type adhesive layer RES is used, the durability of the display device DD may be enhanced, and the optical characteristics may be further improved.

In an embodiment, a fabrication process is disclosed for appropriately bonding the panel PNL and the cover window CW to each other by the resin-type adhesive layer RES. The foregoing will be described in detail below with reference to the following drawings.

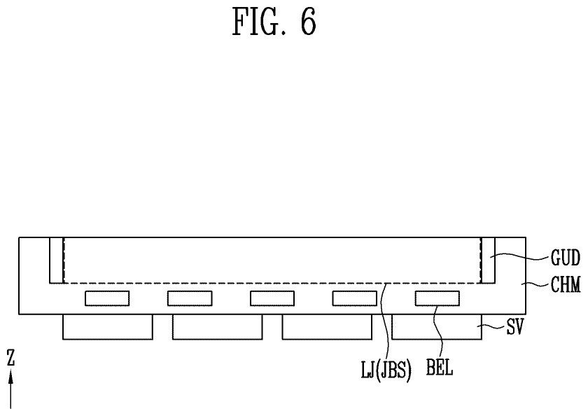

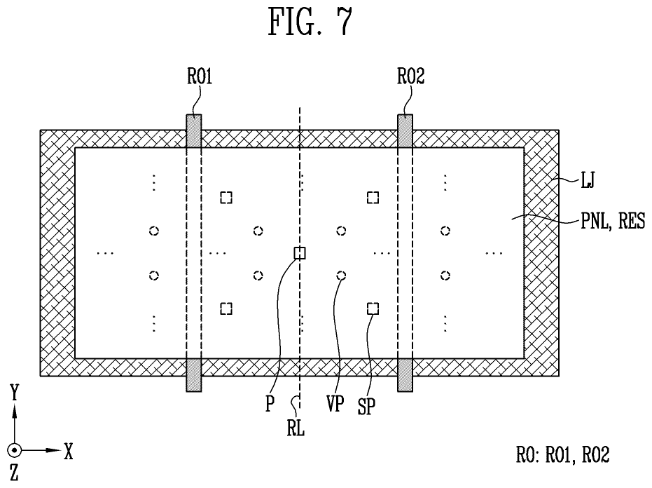

A method of fabricating the display device DD in accordance with an embodiment will be described with reference to FIGS. 2 to 22. For the sake of convenience in explanation, descriptions of content that overlap the contents described above will be simplified or omitted.

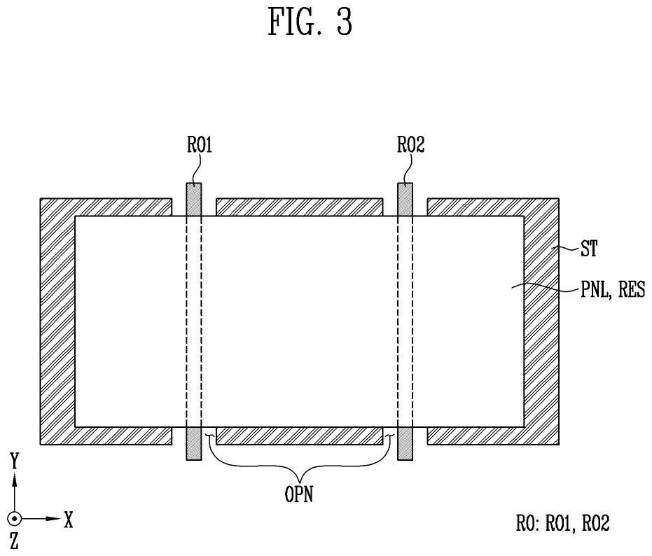

FIG. 2 is a schematic flowchart illustrating a method of fabricating the display device DD in accordance with an embodiment. FIGS. 3 to 22 are schematic views illustrating, by process steps, the method of fabricating the display device DD in accordance with an embodiment.

FIGS. 3 to 12 illustrate steps included in a step S100 of forming the panel PNL using a first jig LJ among process steps of the method of fabricating the display device DD in accordance with an embodiment. The step S100 of forming the panel PNL using the first jig LJ may be a first forming step.

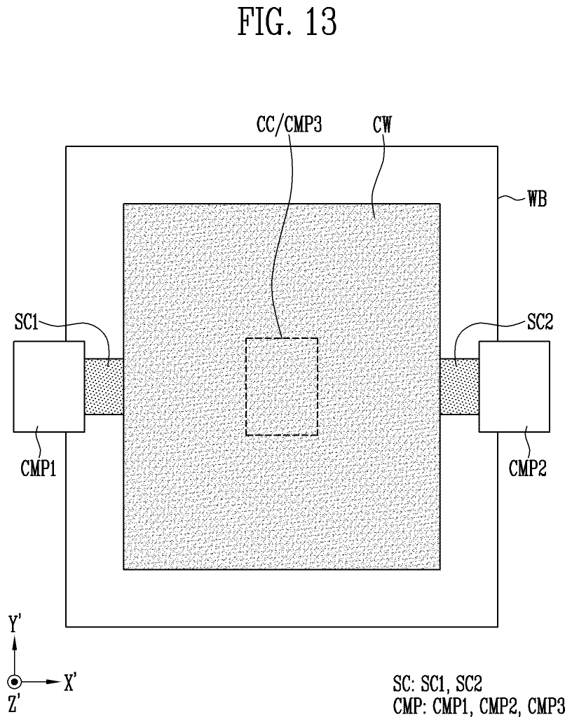

FIGS. 13 to 19 illustrate steps included in a step S200 of forming a cover window CW using a second jig UJ among process steps of the method of fabricating the display device DD in accordance with an embodiment. The step S200 of forming the cover window CW using the second jig UJ may be a second forming step.

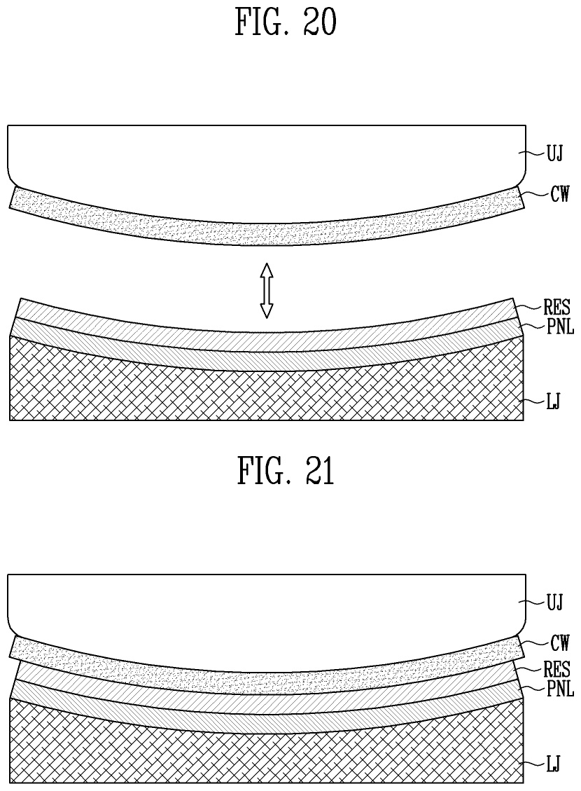

FIGS. 20 to 22 illustrate steps included in the step S200 of bonding the panel PNL and the cover window CW to each other among process steps of the method of fabricating the display device DD in accordance with an embodiment.

Referring to FIG. 2, the method of fabricating the display device DD in accordance with an embodiment may include the step S100 of forming the panel PNL using a lower jig, the step S200 of forming the cover window CW using an upper jig, and the step S300 of bonding the panel PNL and the cover window CW to each other using the resin-type adhesive layer RES.

In an embodiment, the sequence in which the step S100 of forming the panel PNL using the lower jig and the step S200 of forming the cover window CW using the upper jig are performed is not particularly limited. For example, after the step S100 of forming the panel PNL using the lower jig is performed, the step S200 of forming the cover window CW using the upper jig may be performed. In another example, after the step S200 of forming the cover window CW using the upper jig is performed, the step S100 of forming the panel PNL using the lower jig may be performed. In another example, the step S100 of forming the panel PNL using the lower jig and the step S200 of forming the cover window CW using the upper jig may be performed in the same process time period.

Hereinafter, for the sake of convenience in explanation, the step S100 of forming the panel PNL using the lower jig will be described, and then the step S200 of forming the cover window CW using the upper jig will be described.

Referring to FIGS. 3 to 12, the step S100 of forming the panel PNL using the lower jig is illustrated, along with components included in the apparatus for fabricating the display device DD. In an embodiment, the apparatus for fabricating the display device DD illustrated in FIGS. 3 to 12 may be a first fabrication apparatus.

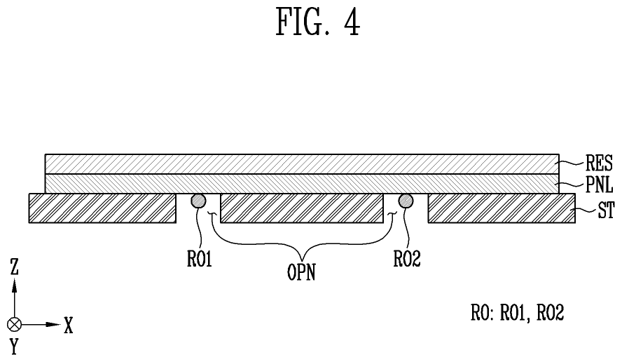

Referring to FIGS. 3 and 4, at the step S100 of forming the panel PNL using the lower jig, the panel PNL may be provided and placed (or disposed) on a stage ST.

The apparatus for fabricating the display device DD in accordance with an embodiment may include the stage ST and a roller RO.

The stage ST may form a base on which the panel PNL is placed. The stage ST may move in upward and downward directions (e.g., in a positive direction and a negative direction of a Z-axis). The stage ST may include an opening OPN that exposes at least a portion of a lower surface of the panel PNL in case that the panel PNL is placed (or disposed) on the stage ST. The stage ST may include a material having relatively rigid characteristics, and may stably support the panel PNL.

The roller RO may extend in a direction (e.g., a Y-axis direction Y). The roller RO may have a circular cross-section. For example, the roller RO may have a cylindrical shape.

The roller RO may include rollers RO spaced apart from each other in a direction (e.g., an X-axis direction X). For example, the rollers RO may include a first roller RO1 and a second roller RO2. The number of rollers RO is not limited to a specific example. Hereinafter, for the sake of convenience of explanation, the description will be based on an embodiment in which the rollers RO include a first roller RO1 and a second roller RO2.

At the step S100, the panel PNL may be provided, the resin-type adhesive layer RES may be placed (or disposed) on the panel PNL, and the panel PNL and the resin-type adhesive layer RES may be placed (or disposed) on the stage ST.

At the step S100, the first and second rollers RO1 and RO2 may be adjacent to the panel PNL and the resin-type adhesive layer RES in a Z-axis direction Z. The rollers RO may be respectively placed in the openings OPN formed in the stage ST. Therefore, the first and second rollers RO1 and RO2 may be adjacent (e.g., directly adjacent) to the lower surface of the panel PNL. The first and second rollers RO1 and RO2 may support the lower portion of the panel PNL.

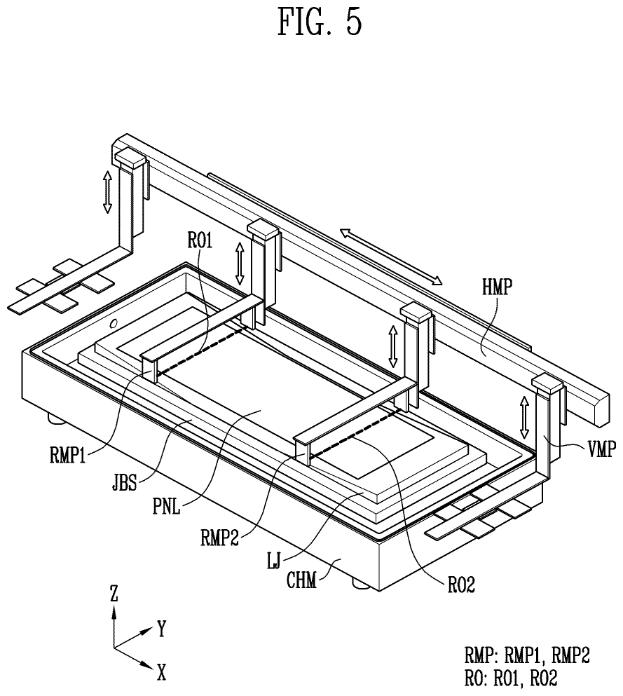

Referring to FIGS. 5 to 8, at the step S100 of forming the panel PNL using the lower jig, the rollers RO may support the lower portion of the panel PNL, and the stage ST may be spaced apart from the panel PNL. The panel PNL may be placed (or disposed) on the first jig LJ.

The apparatus for fabricating the display device DD may include a chamber CHM, a jig base JBS, the first jig LJ, a roller moving member RMP, a first transfer member HMP, and a second transfer member VMP. In an embodiment, the apparatus for fabricating the display device DD may further include a guide component GUD, a servo component SV, and a bellows BEL.

The chamber CHM may form a process space for forming the panel PNL and the resin-type adhesive layer RES. For example, the chamber CHM may form at least a portion of the housing. The chamber CHM may form a space for receiving the chamber CHM and the first jig LJ therein.

The jig base JBS may be located (or disposed) in the chamber CHM. The jig base JBS may form an area where the first jig LJ is located (or disposed). The jig base JBS may include a rigid material, and may stably support a lower portion of the first jig LJ.

The first jig LJ may be a jig for forming the panel PNL and the resin-type adhesive layer RES. The first jig LJ may secure (or hold) the position of the panel PNL during a process of forming the panel PNL and the resin-type adhesive layer RES.

The first jig LJ may be the lower jig. The first jig LJ may be located (or disposed) in the chamber CHM, and may be placed (or disposed) on the jig base JBS.

The first jig LJ may include a curved surface. The first jig LJ may include a concave surface. The concave surface of the first jig LJ may face the lower portion of the panel PNL. The curved surface of the first jig LJ may have a shape corresponding to the form of the panel PNL that has been shaped.

The roller moving member RMP may be connected to the rollers RO. The roller moving member RMP may be located (or disposed) over the panel PNL and the resin-type adhesive layer RES. The roller moving member RMP may move the rollers RO in a first direction (e.g., a horizontal direction). For example, the roller moving member RMP may move the first and second rollers RO1 and RO2 in the X-axis direction X and a direction opposite to the X-axis direction X.

A portion of the roller moving member RMP may be coupled to a side of each of the rollers RO, and another portion of the roller moving member RMP may be coupled to another side of the roller RO. Accordingly, the roller moving member RMP may be located (or disposed) over the panel PNL to move the rollers RO located (or disposed) under the panel PNL. In an embodiment, the roller moving member RMP may have a gantry shape.

In an embodiment, the roller moving member RMP may include a first roller moving member RMP1 that is connected to the first roller RO1 to move the first roller RO1, and a second roller moving member RMP2 that is connected to the second roller RO2 to move the second roller RO2.

The first transfer member HMP may move the roller moving member RMP in the horizontal direction. The first transfer member HMP may extend in the X-axis direction. The first transfer member HMP may move the first and second roller moving members RMP1 and RMP2 in the X-axis direction X or the direction opposite to the X-axis direction X. Accordingly, the rollers RO may move in the X-axis direction X or the direction opposite to the X-axis direction X.

The second transfer member VMP may move the roller moving member RMP in a second direction (e.g., a vertical direction). The second transfer member VMP may extend in the Z-axis direction. The second transfer member VMP may move the first and second roller moving members RMP1 and RMP2 in the Z-axis direction Z or the direction opposite to the Z-axis direction Z. Accordingly, the rollers RO may move in the Z-axis direction Z or the direction opposite to the Z-axis direction Z.

In the description, unless specifically mentioned otherwise, the rollers RO may be understood to move based on the operation of the roller moving member RMP, the first transfer member HMP, and the second transfer member VMP. The operation of the roller moving member RMP, the first transfer member HMP, and the second transfer member VMP may be implemented based on generally known mechanical operation equipment.

The apparatus for fabricating the display device DD in accordance with an embodiment may include a pin P and a vacuum member VP. In an embodiment, the apparatus for fabricating the display device DD may further include a support component SP.

The pin P may be located (or disposed) under the panel PNL. The pin P may extend in the Z-axis direction Z. In an embodiment, the pin P may overlap a central portion of the panel PNL.

In the description, the central portion of the panel PNL may refer to a center portion and a peripheral portion surrounding the center portion.

During the process of forming the panel PNL and the resin-type adhesive layer RES, the pin P may be coupled (e.g., by suction force) to the lower portion of the panel PNL, pulling a portion of the panel PNL. For example, the pin P may be coupled to the central portion of the lower portion of the panel PNL during the process of forming the panel PNL, and may pull the central portion of the lower portion of the panel PNL.

An end portion of the pin P adjacent to the panel PNL may be attached to the panel PNL by suction. For example, the pin P may include a suction pad SUC. The suction pad SUC may couple the pin P to the lower portion of the panel PNL.

The pin P may move in the Z-axis direction Z or the direction opposite to the Z-axis direction Z. For example, the pin P may be moved by a separately provided servomotor (e.g., the servo component SV).

The pin P may be coupled to the lower portion of the panel PNL at a stage preceding the coupling of the vacuum member VP during the process of forming the panel PNL and the resin-type adhesive layer RES. Accordingly, the panel PNL and the resin-type adhesive layer RES may be formed preferentially in the central portion relative to the periphery.

The vacuum member VP may be located (or disposed) under the panel PNL. The vacuum member VP may extend in the Z-axis direction Z. The vacuum member VP may include vacuum members.

The vacuum member VP may move in upward and downward directions. The vacuum member VP may move in the Z-axis direction Z or the direction opposite to the Z-axis direction Z. For example, the pin P may be moved by a separately provided servomotor.

The vacuum member VP may include an auxiliary suction pad SUC_S. The vacuum member VP may be coupled to the lower portion of the panel PNL by the auxiliary suction pad SUC_S in a manner similar to that of the pin P. During the process of forming the panel PNL and the resin-type adhesive layer RES, the vacuum member VP may be coupled (e.g., by suction force) to the lower portion of the panel PNL, pulling a portion of the panel PNL.

The vacuum members VP may be placed (or disposed) around the central portion of the panel PNL. For example, the vacuum members VP may be placed (or disposed) around the pin P. The vacuum members VP may be located (or disposed) between the first roller RO1 and the second roller RO2. The vacuum members VP may be located (or disposed) on a side opposite to the first roller RO1. The vacuum members VP may be located (or disposed) on a side opposite to the second roller RO2. In an embodiment, the vacuum members VP may include a first vacuum member VP1 and a second vacuum member VP2. In an embodiment, the first vacuum member VP1 may be located (or disposed) on a first side of the pin P. The first vacuum member VP1 may be located (or disposed) on the first side of the pin P on which the first roller RO1 is placed. The second vacuum member VP2 may be located (or disposed) on a second side of the pin P. The second vacuum member VP2 may be located (or disposed) on the second side of the pin P on which the second roller RO2 is placed. The number and arrangement positions of the vacuum members VP are not limited to specific examples.

The positions at which the vacuum members VP are arranged may be symmetrical with respect to the central portion of the panel PNL (e.g., a position at which the pin P is located). For example, the positions at which the vacuum members VP are arranged may be symmetrical with respect to a reference line RL. The reference line RL may be an imaginary line which passes through the pin P and extends in the Y-axis direction. For example, during the process of forming the panel PNL and the resin-type adhesive layer RES, the panel PNL and the resin-type adhesive layer RES may be uniformly shaped.

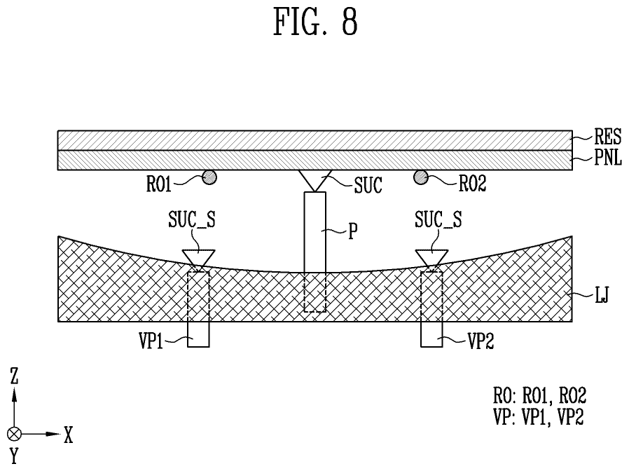

The support component SP may be located (or disposed) under the panel PNL. The support component SP may extend in the Z-axis direction Z. The support component SP may include support components. The support component SP may have a curved shape at a position adjacent to the lower portion of the panel PNL. In an embodiment, the support component SP may support the lower portion of the panel PNL during the process of forming the panel PNL and the resin-type adhesive layer RES, thereby securing (ore ensuring) mechanical stability of the panel PNL. For the sake of convenience in explanation, the support component SP is not illustrated in FIGS. 8 to 12.

The guide component GUD may be located (or disposed) in the chamber CHM. The guide component GUD may extend in the Z-axis direction Z. The guide component GUD may guide the position of the first jig LJ and/or the jig base JBS. For example, the guide component GUD may be formed on the first jig LJ and/or each of a first side and a second side of the jig base JBS. The guide component GUD may be located (or disposed) adjacent to an edge portion of the first jig LJ and/or the jig base JBS, thereby maintaining the lateral position of the first jig LJ and/or the jig base JBS.

The servo component SV may be placed (or disposed) on a periphery of the chamber CHM (e.g., under the lower surface of the chamber CHM). The servo component SV may move the pin P, the vacuum member VP, and the support component SP in the upward and downward directions. For example, the servo component SV may include a servomotor, and may further include a ball screw, a guide, and the like for more precise operation.

The bellows BEL may be located (or disposed) in the chamber CHM. The bellows BEL may be a component that forms a vacuum state. For example, the bellows BEL may allow the pin P and the vacuum member VP to maintain a vacuum state for securing (or holding) the panel PNL through suction.

At the step S100, with the rollers RO supporting the lower portion of the panel PNL, the stage ST may be spaced apart from the panel PNL, and the first jig LJ may be positioned under the panel PNL. Accordingly, the panel PNL may be supported by the rollers RO and located (or disposed) adjacent to the first jig LJ. At the step S100, the panel PNL may be spaced apart from the first jig LJ in the Z-axis direction Z.

At the step S100, the pin P may be coupled to the lower portion (e.g., the central portion) of the panel PNL by the suction pad SUC. The pin P may be attached to the central portion of the panel PNL by suction, and the vacuum members VP formed around the pin P may not be attached to the lower portion of the panel PNL by suction.

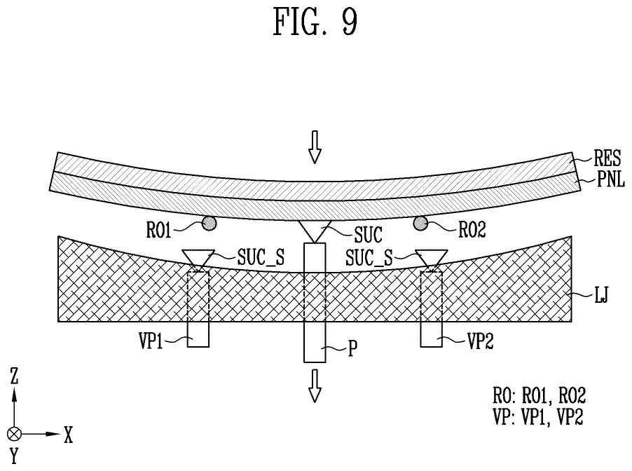

Referring to FIG. 9, the pin P may pull the panel PNL and the resin-type adhesive layer RES.

At the step S100, the first and second rollers RO1 and RO2 may support the lower portion of the panel PNL. The pin P may pull the panel PNL in the downward direction (e.g., the direction opposite to the Z-axis direction Z, e.g., the direction of gravity) between the first and second rollers RO1 and RO2. In an embodiment, with the first and second rollers RO1 and RO2 supporting the lower portion of the panel PNL around the pin P, the pin P, which is positioned closer to the central portion of the panel PNL compared to the first and second rollers RO1 and RO2, may apply external force to the panel PNL in the downward direction, thereby causing the central portion of the panel PNL to be formed earlier than the portions of the panel PNL that are farther from the central portion.

At the step S100, the vacuum members VP may be spaced apart from the lower portion of the panel PNL, and may not be attached to the panel PNL.

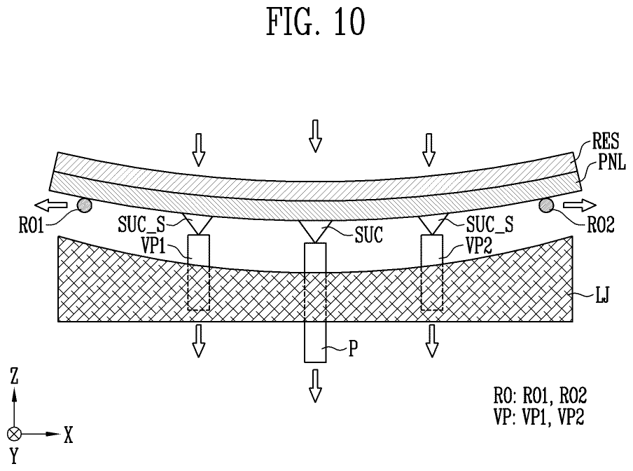

Referring to FIG. 10, the pin P and the vacuum members VP may pull the panel PNL and the resin-type adhesive layer RES. The rollers RO may move under the panel PNL.

At the step S100, the vacuum members VP may be coupled to the lower portion (e.g., the peripheral portion) of the panel PNL by the auxiliary suction pad SUC_S. The first and second rollers RO1 and RO2 may support the lower portion of the panel PNL. The pin P and the vacuum members VP may pull the panel PNL in the downward direction (e.g., the direction opposite to the Z-axis direction Z, e.g., the direction of gravity) between the first and second rollers RO1 and RO2.

At the step S100, the rollers RO may continuously support the lower portion of the panel PNL. The rollers RO may move toward the edge portion of the panel PNL to prevent overlap with the vacuum members VP. Therefore, the rollers RO enables the panel PNL and the resin-type adhesive layer RES to be sequentially formed from the central portion toward the edge portion.

In an embodiment, the rollers RO may apply external force to the lower portion of the panel PNL upward. For example, the panel PNL may be pulled downward by the pin P and the vacuum members VP at the relatively central portion and supported by the rollers RO moving outward at the relatively edge portion.

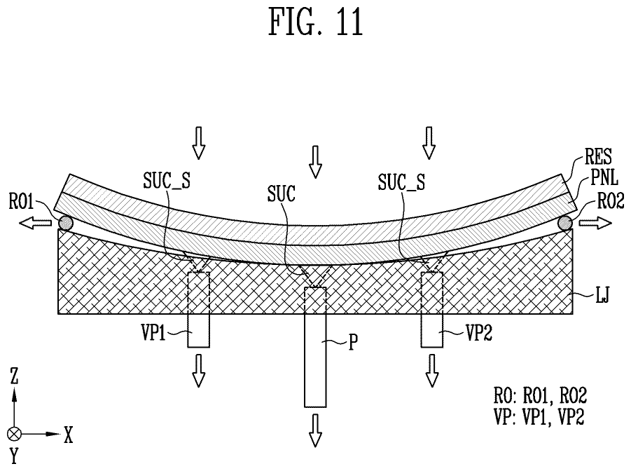

Referring to FIG. 11, the rollers RO may move to the outermost edge portion of the lower portion of the panel PNL. The lower portion of the panel PNL may be adjacent (e.g., directly adjacent) to a portion of the first jig LJ.

At the step S100, because the rollers RO under the panel PNL support the lower portion of the panel PNL in a direction toward the edge portion of the panel PNL, a range within which the panel PNL is placed (or disposed) on the first jig LJ may be controlled. For example, at the step S100, the lower portion of the panel PNL may sequentially become adjacent (e.g., directly adjacent) to the first jig LJ, starting from the central portion. Accordingly, the lower portion of the panel PNL may be placed (or disposed) on the first jig LJ in a direction from the central portion toward the edge portion, thereby enabling the panel PNL and the resin-type adhesive layer RES to be formed in a form corresponding to the curved shape of the first jig LJ.

At the step S100, the central portion of the lower portion of the panel PNL may contact a portion of the first jig LJ, and the edge portion of the lower portion of the panel PNL may be physically spaced apart from the first jig LJ by the rollers RO.

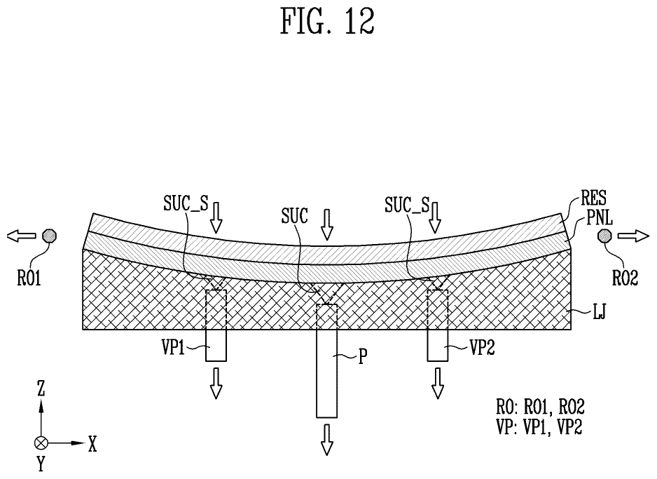

Referring to FIG. 12, the rollers RO may be moved from the central portion of the panel PNL to the edge portion and be spaced apart from the panel PNL. The panel PNL may be pulled by the pin P and the vacuum members VP, so that the lower portion of the panel PNL may be placed (or disposed) on the first jig LJ.

At the step S100, the rollers RO may not support the lower portion of the panel PNL. The entire lower portion of the panel PNL may be adjacent (e.g., directly adjacent) to the curved surface of the first jig LJ. Accordingly, the panel PNL and the resin-type adhesive layer RES may be formed to correspond to the curved shape of the first jig LJ.

Accordingly, the formed panel PNL and the formed resin-type adhesive layer RES that are placed (or disposed) on the curved surface of the first jig LJ may be provided.

As described above, through the process of forming the panel PNL and the resin-type adhesive layer RES, a structure in which the resin-type adhesive layer RES based on resin material is placed (or disposed) on the panel PNL may also be appropriately shaped. Because the panel PNL and the resin-type adhesive layer RES are sequentially formed in a direction from the central portion to the edge portion, the panel PNL and the resin-type adhesive layer RES may be thoroughly shaped. For example, the risk of an air layer or foreign substances being formed between the panel PNL and the resin-type adhesive layer RES may be reduced. Accordingly, the need for process equipment, such as an air blower, to remove foreign substances may be reduced, thereby further simplifying the process. Furthermore, even in the case where the panel PNL and the first jig LJ have different curvatures, the panel PNL and the first jig LJ may reliably come into close contact with each other.

Referring to FIGS. 13 to 19, the step S200 of forming the cover window CW using the second jig UJ is illustrated, along with components included in the apparatus for fabricating the display device DD. The apparatus for fabricating the display device DD illustrated in FIGS. 13 to 19 may be a second fabrication apparatus.

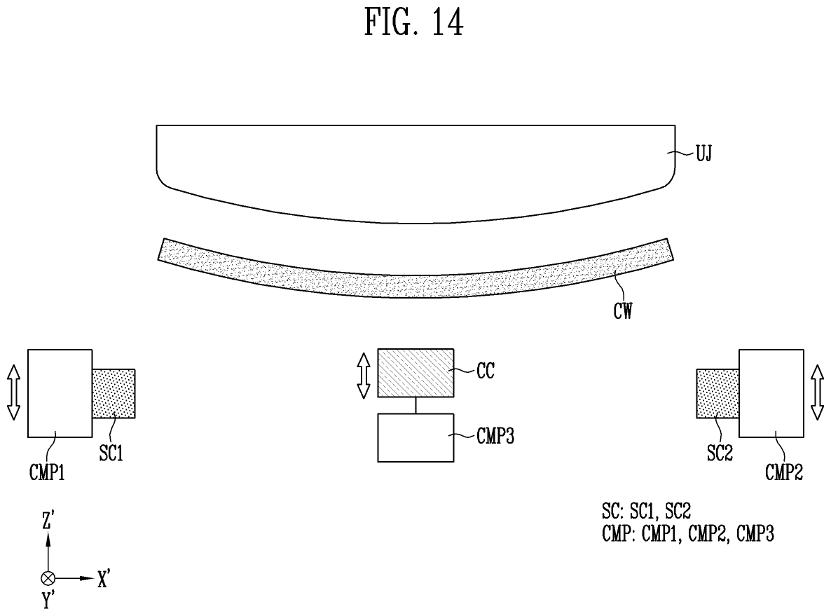

Referring to FIGS. 13 and 14, at the step S200 of forming the cover window CW using the second jig UJ, the cover window CW may be provided and placed (or disposed) on a window base WB.

The apparatus for fabricating the display device DD in accordance with an embodiment may include the window base WB, a side clamp SC, a center clamp CC, a clamp moving member CMP, and the second jig UJ.

The window base WB may form a base on which the cover window CW is placed. The window base WB may have a material having relatively rigid characteristics, and may stably support the cover window CW. In an embodiment, the window base WB may adjust the pose (or position) of the cover window CW.

The side clamp SC may be coupled to sides of the cover window CW. The side clamp SC may be fixed to the sides of the cover window CW by various methods. For example, the side clamp SC may be implemented by various methods, such as mechanical clamping, electrostatic chucking, or pneumatic clamping using a cylinder, and embodiments are not limited to a specific example.

The side clamp SC may include a first side clamp SC1 and a second side clamp SC2. The first side clamp SC1 may be coupled to a first side of the cover window CW. The second side clamp SC2 may be coupled to a second side of the cover window CW.

The side clamp SC may move in upward and downward directions. The side clamp SC may move in a Z-axis direction Z′ or a direction opposite to the Z-axis direction Z′.

The center clamp CC may be coupled to a central portion of the cover window CW. The center clamp CC may be fixed to the central portion of the cover window CW by various methods. For example, the center clamp CC may be implemented by various methods, such as mechanical clamping, electrostatic chucking, or pneumatic clamping using a cylinder, and embodiments are not limited to a specific example.

The center clamp CC may move in upward and downward directions. The center clamp CC may move in the Z-axis direction Z′ or the direction opposite to the Z-axis direction Z′.

The clamp moving member CMP may transfer the positions of the side clamp SC and the center clamp CC. The clamp moving member CMP may include a first clamp moving member CMP1, a second clamp moving member CMP2, and a third clamp moving member CMP3.

The first clamp moving member CMP1 may transfer the first side clamp SC1 in the Z-axis direction Z′ or the direction opposite to the Z-axis direction Z′. The second clamp moving member CMP2 may transfer the second side clamp SC2 in the Z-axis direction Z′ or the direction opposite to the Z-axis direction Z′. The third clamp moving member CMP3 may move the center clamp CC in the Z-axis direction Z′ or the direction opposite to the Z-axis direction Z′.

The clamp moving member CMP may be implemented by various methods, such as using an actuator, or a pneumatic system. For example, the third clamp moving member CMP3 may include a cylinder or the like. However, embodiments are not limited to a specific example.

Unless specifically mentioned otherwise, the side clamp SC and the center clamp CC may be understood to move based on the operation of the clamp moving member CMP.

The second jig UJ may be a jig provided to form the cover window CW. The second jig UJ may be the upper jig. The second jig UJ may be placed (or disposed) on the window base WB, and may be placed (or disposed) on the cover window CW.

The second jig UJ may include a curved surface. The second jig UJ may include a convex surface. The convex surface of the second jig UJ may face an upper portion of the cover window CW. The curved surface of the second jig UJ may have a shape corresponding to the form of the cover window CW that has been shaped.

At the step S200, the cover window CW and the second jig UJ spaced apart from the cover window CW may be provided. The cover window CW may be positioned around the side clamps SC and the center clamp CC.

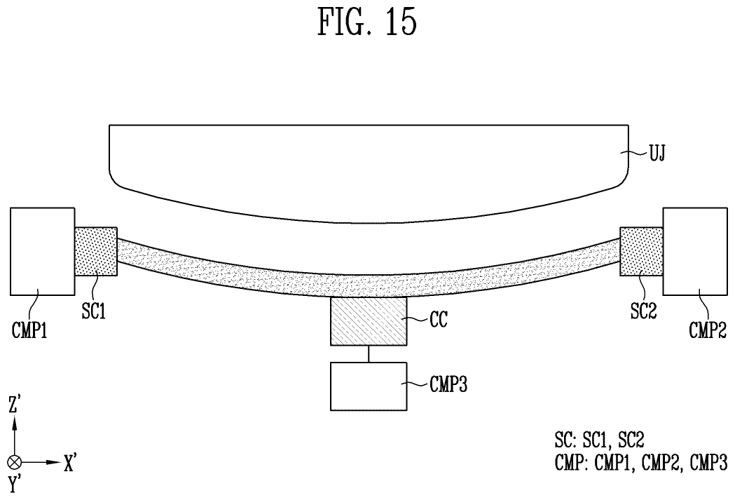

Referring to FIG. 15, the cover window CW may be coupled to the side clamps SC and the center clamp CC.

At the step S200, the center clamp CC may be moved and coupled to the central portion of the lower portion of the cover window CW. The side clamps SC may be moved and coupled to the sides of the cover window CW.

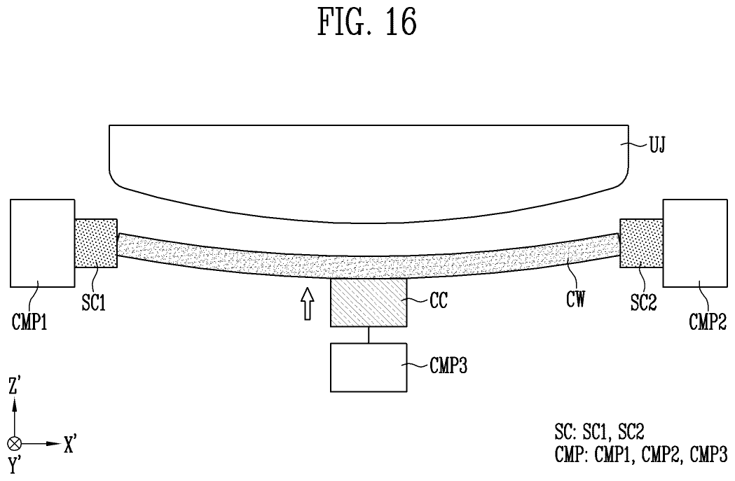

Referring to FIG. 16, at least a portion of the cover window CW may be curved.

At the step S200, the center clamp CC may push the lower portion of the cover window CW in the Z-axis direction Z′. For example, the center clamp CC may push the central portion of the cover window CW in a direction from the cover window CW toward the second jig UJ.

At the step S200, the side clamps SC may secure (or hold) the positions of the sides of the cover window CW in place, and simultaneously, the center clamp CC may push the lower portion of the cover window CW. Accordingly, the central portion of the cover window CW may be relatively close to the second upper jig UJ. Consequently, the curvature of the cover window CW may be reduced.

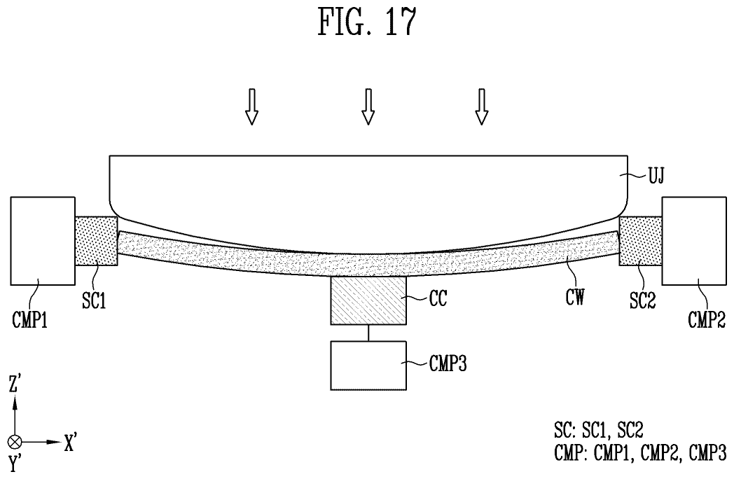

Referring to FIG. 17, the second jig UJ may move to be adjacent to the cover window CW.

At the step S200, the position of the cover window CW may be secured (or maintained) in place by the side clamps SC and the center clamp CC, and simultaneously, the second jig UJ may move toward the cover window CW.

At the step S200, the second jig UJ may be adjacent (e.g., directly adjacent) to a central portion of an upper surface of the cover window CW, and may be physically spaced apart from an edge portion of the upper surface of the cover window CW. A protruding portion formed by the convex surface of the second jig UJ may come into contact with the cover window CW. In an embodiment, because the cover window CW has a reduced curvature at the previously described step, the central portion of the cover window CW may preferentially come into contact with the second jig UJ.

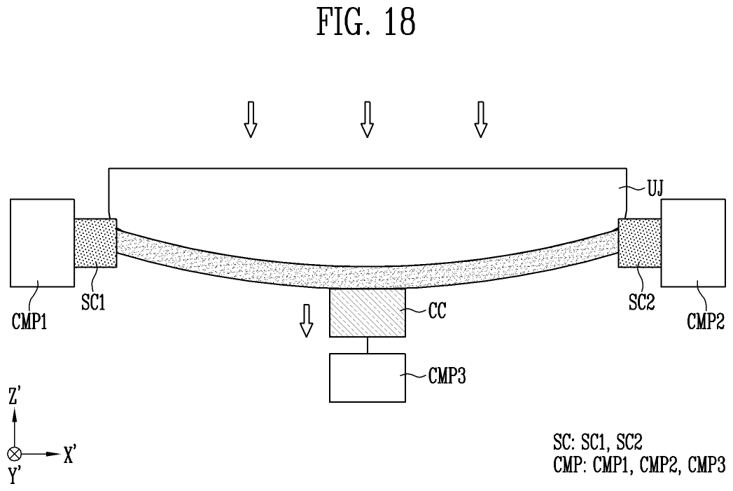

Referring to FIG. 18, the second jig UJ may move to be adjacent to the cover window CW, and the center clamp CC may move downward with being coupled with the lower surface of the cover window CW. Accordingly, the cover window CW may be sequentially placed (or disposed) on the second jig UJ in a direction from the central portion toward the edge portion.

At the step S200, the cover window CW may be formed to correspond to the curved form of the second jig UJ. For example, with the positions of the sides of the cover window CW secured (or maintained) in place by the side clamps SC, the second jig UJ and the center clamp CC may apply external force to the cover window CW in the direction opposite to the Z-axis direction Z′ (e.g., in a downward direction, e.g., the direction of gravity). Consequently, the upper surface of the cover window CW may come into close contact with the second jig UJ, and the cover window CW may be formed to correspond to the form of the second jig UJ.

In an embodiment, due to the operation of the center clamp CC, the side clamps SC, and the second jig UJ, the cover window CW may sequentially become adjacent to the second jig UJ in a direction from the central portion toward the edge portion. For example, because the cover window CW is sequentially formed in a direction from the central portion toward the edge portion, the cover window CW may be thoroughly shaped. Furthermore, although the curvatures of the cover window CW and the second jig UJ differ from each other, the cover window CW and the second jig UJ may reliably come into close contact with each other.

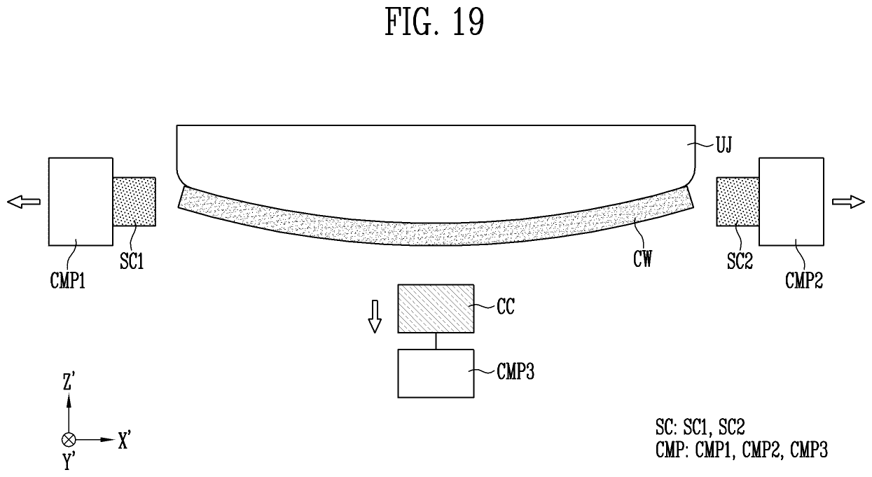

Referring to FIG. 19, after the cover window CW is placed (or disposed) on (e.g., brought into close contact with) the curved surface of the second jig UJ, the side clamps SC and the center clamp CC that are coupled to the cover window CW may be spaced apart from the cover window CW.

At the step S200, after the cover window CW comes into close contact with the second jig UJ to correspond to the curved surface of the second jig UJ, the coupling of the side clamps SC and the center clamp CC to the cover window CW may be released.

Accordingly, the formed cover window CW placed (or disposed) on the curved surface of the second jig UJ may be provided.

Referring to FIGS. 20 to 22, the step S200 of coupling the panel PNL and the cover window CW is illustrated.

Referring to FIG. 20, as the components provided according to the aforementioned steps, the formed panel PNL and the formed resin-type adhesive layer RES may be provided on the first jig LJ, and the formed cover window CW may be provided under the second jig UJ.

At the step S300, the cover window CW and the resin-type adhesive layer RES may be arranged to face each other. The first jig LJ may be located (or disposed) at a lower position, and the second jig UJ may be located (or disposed) at an upper position.

Referring to FIG. 21, the first and second jigs LJ and UJ may move to be adjacent to each other, and the panel PNL and the cover window CW may be coupled to each other by the resin-type adhesive layer RES.

The step S300 may be performed with the panel PNL and the cover window CW previously shaped. Accordingly, the process of coupling the panel PNL and the cover window CW may be more efficiently performed.

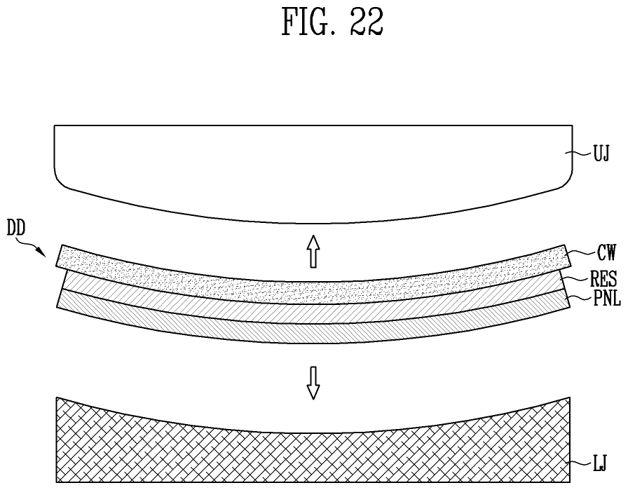

Referring to FIG. 22, after the panel PNL and the cover window CW are coupled to each other by the resin-type adhesive layer RES, the first jig LJ may be spaced apart from the panel PNL, and the second jig UJ may be spaced apart from the cover window CW.

At the present step, the panel PNL and the cover window CW that are attached to each other by the resin-type adhesive layer RES may be provided, and the display device DD in accordance with an embodiment may be provided.

Various embodiments of the disclosure may provide a method of fabricating a display device and an apparatus for fabricating the display device in which a display panel and a cover window are thoroughly attached to each other.

Various embodiments of the disclosure may provide a method of fabricating a display device and an apparatus for fabricating the display device in which a process of forming the display panel and the cover window may be appropriately performed.

Various embodiments of the disclosure may provide a method of fabricating a display device and an apparatus for fabricating the display device in which jigs for performing the forming process may reliably secure (or hold) the display panel and the cover window.

Various embodiments of the disclosure may provide a method of fabricating a display device and an apparatus for fabricating the display device in which process steps may be simplified.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A method of fabricating a display device, the method comprising:
forming a panel and a resin-type adhesive layer using a first jig;
forming a cover window using a second jig; and
coupling the panel to the cover window.

2. The method of claim 1, wherein the forming of the panel and the resin-type adhesive layer comprises:
placing the panel and the resin-type adhesive layer on a stage, the stage including an opening; and
supporting, by a roller, a lower surface of the panel that is exposed through the opening of the stage.

3. The method of claim 2, wherein the forming of the panel and the resin-type adhesive layer comprises:
spacing the stage and the panel apart from each other while the roller supports the lower surface of the panel; and
placing the first jig including a curved surface under a lower portion of the panel.

4. The method of claim 3, wherein the forming of the panel and the resin-type adhesive layer comprises:
attaching a pin to a central portion of the lower portion of the panel; and
pulling the panel by the pin while the roller supports the lower portion of the panel.

5. The method of claim 4, wherein
the forming of the panel and the resin-type adhesive layer comprises:
attaching vacuum members to a peripheral portion surrounding the central portion of the panel;
pulling the panel by the vacuum members; and
moving the roller from the central portion toward an edge portion of the panel, and
attaching the vacuum members to the peripheral portion surrounding the central portion of the panel is performed after the attaching of the pin to the central portion of the lower portion of the panel.

6. The method of claim 5, wherein the forming of the panel and the resin-type adhesive layer comprises sequentially placing the panel on the first jig in a direction from the central portion toward the edge portion.

7. The method of claim 1, wherein
the forming of the cover window comprises:
coupling a center clamp to a central portion of a lower portion of the cover window;
coupling a side clamp to a side of the cover window; and
pushing, by the center clamp, the cover window in a direction from the cover window toward the second jig while the side clamp maintains a position of the side of the cover window.

8. The method of claim 7, wherein
the pushing of the cover window comprises reducing a curvature of the cover window, and
the forming of the cover window comprises bringing the second jig adjacent to the cover window such that the central portion of the cover window contacts the second jig.

9. The method of claim 8, wherein the forming of the cover window comprises:
pushing the cover window by the second jig; and
pulling the cover window by the center clamp.

10. The method of claim 9, wherein the forming of the cover window comprises sequentially placing the cover window on the second jig in a direction from the central portion toward the side such that the cover window is formed to correspond to the second jig.

11. The method of claim 9, wherein the coupling of the panel and the cover window comprises coupling the formed panel and the formed resin-type adhesive layer with the formed cover window.

12. An apparatus for fabricating a display device, the apparatus comprising:
a first fabrication apparatus that forms a panel; and
a second fabrication apparatus that forms a cover window, wherein
the first fabrication apparatus comprises:
a first jig including a curved surface oriented toward the panel;
a pin coupled to a central portion of a lower portion of the panel, the pin being movable in upward and downward directions; and
rollers supporting the panel from below the panel, the rollers being movable from the central portion of the panel toward an edge portion of the panel, and the second fabrication apparatus comprises:
a second jig including a curved surface oriented toward the cover window;
a center clamp coupled to a central portion of a lower portion of the cover window, the center clamp being movable in upward and downward directions; and
side clamps coupled to sides of the cover window.

13. The apparatus of claim 12, wherein
the rollers comprise a first roller and a second roller spaced apart from each other and each having a form extending in a direction, and
the curved surface of the first jig is oriented toward the lower portion of the panel.

14. The apparatus of claim 13, wherein the pin pulls the central portion of the panel while the rollers support the lower portion of the panel.

15. The apparatus of claim 14, wherein the pin comprises a suction pad coupled to the lower portion of the panel.

16. The apparatus of claim 14, further comprising:
vacuum members disposed under the lower portion of the panel and coupled to the panel around the central portion of the panel, the vacuum members being movable in the upward and downward directions.

17. The apparatus of claim 16, wherein the vacuum members comprise:
a first vacuum member disposed on a first side of the pin on which the first roller is positioned, and
a second vacuum member disposed on a second side of the pin on which the second roller is positioned.

18. The apparatus of claim 17, wherein
the vacuum members pull the panel after the pin pulls the lower portion of the panel, and
the rollers support the lower portion of the panel and move from the central portion of the panel toward the edge portion while the pin and the vacuum members pull the panel.

19. The apparatus of claim 12, wherein the second jig includes a convex surface facing the cover window.

20. The apparatus of claim 19, wherein
the center clamp pushes the cover window in a direction from the cover window toward the second jig while the side clamps hold the cover window, and
the second jig moves in a direction from the second jig toward the cover window while the side clamps hold the cover window.
